(19) United States
(12) Patent Application Publication
(10) Pub. No.: US 2026/0013240 A1
(43) Pub. Date: Jan. 8, 2026

(54) SOLID-STATE IMAGE SENSOR

(71) Applicant: Samsung Electronics Co., Ltd., Suwon-si (KR)

(72) Inventor: Kazufumi SHIOZAWA, Yokohama (JP)

(73) Assignee: Samsung Electronics Co., Ltd., Suwon-si (KR)

(21) Appl. No.: 19/214,863

(22) Filed: May 21, 2025

(30) Foreign Application Priority Data
Jul. 5, 2024 (JP) 2024-108909
Oct. 7, 2024 (KR) 10-2024-0135975

(51) Int. Cl. H10F 39/18; H10F 39/00

(52) U.S. Cl. CPC H10F 39/182; H10F 39/8023; H10F 39/8063; H10F 39/807; H10F 39/811

(57) ABSTRACT

A solid-state image sensor includes a plurality of photoelectric converters arranged in a horizontal direction such that the plurality of photoelectric converters at least partially overlap each other in the horizontal direction, the plurality of photoelectric converters at least partially defining separate, respective pixels of a plurality of pixels in the solid-state image sensor, a plurality of on-chip lenses on one side of separate, respective photoelectric converters of the plurality of photoelectric converters in a perpendicular lamination direction, a wiring layer on another side of each photoelectric converter of the plurality of photoelectric converters in the lamination direction, and a pixel isolator configured to isolate the plurality of pixels from each other, wherein the pixel isolator includes a metal layer and a dielectric layer, and in the horizontal direction, the pixel isolator includes separate first regions defined by the metal layer second regions defined by the dielectric layer.

### CROSS-REFERENCE TO RELATED APPLICATIONS

This application claims the benefits of Japanese Patent Application No. 2024-108909, filed on Jul. 5, 2024 in the Japanese Intellectual Property Office, and Korean Patent Application No. 10-2024-0135975, filed on Oct. 7, 2024 in the Korean Intellectual Property Office, the disclosures of each of which are incorporated by reference herein in their entirety.

### BACKGROUND

The inventive concepts relate to solid-state image sensors.

As solid-state image sensors, image sensors are typically configured to collect light that has been incident thereon. In solid-state image sensors according to the related art, an isolation layer, which has a material for absorbing light in a horizontal direction perpendicular to a direction in which a photoelectric converter is laminated, is configured to surround the photoelectric converters. Therefore, color mixing is reduced by preventing light from leaking into adjacent pixels. As a result, the modulation transfer function (MTF) value improves, but the quantum efficiency (QE) deteriorates due to the large optical absorption in the isolation layer, which is undesirable.

### SUMMARY

Some example embodiments of the inventive concepts provide a solid-state image sensor having improved reliability. The image sensor may be capable of optimizing both quantum efficiency (QE) and modulation transfer function (MTF) simultaneously.

According to some example embodiments of the inventive concepts, a solid-state image sensor may include a plurality of photoelectric converters arranged in a horizontal direction such that the plurality of photoelectric converters at least partially overlap each other in the horizontal direction, the plurality of photoelectric converters at least partially defining separate, respective pixels of a plurality of pixels in the solid-state image sensor. The solid-state image sensor may include a plurality of on-chip lenses on one side of separate, respective photoelectric converters of the plurality of photoelectric converters in a lamination direction, the lamination direction perpendicular to the horizontal direction. The solid-state image sensor may include a wiring layer on another side of each photoelectric converter of the plurality of photoelectric converters in the lamination direction. The solid-state image sensor may include a pixel isolator configured to isolate the plurality of pixels from each other. The pixel isolator may include a metal layer and a dielectric layer. In the horizontal direction, the pixel isolator may include separate first regions defined by the metal layer is located and second regions defined by at least the dielectric layer.

According to some example embodiments of the inventive concepts, a solid-state image sensor may include a plurality of photoelectric converters arranged in a horizontal direction such that the plurality of photoelectric converters at least partially overlap each other in the horizontal direction, the plurality of photoelectric converters at least partially defining separate, respective pixels of a plurality of pixels in the solid-state image sensor. The solid-state image sensor may include a plurality of on-chip lenses, each separate on-chip lenses of the plurality of on-chip lenses on an upper surface of a separate photoelectric converter of the plurality of photoelectric converters in a lamination direction, the lamination direction perpendicular to the horizontal direction. The solid-state image sensor may include a wiring layer on a lower surface of each photoelectric converter of the plurality of photoelectric converters in the lamination direction. The solid-state image sensor may include a pixel isolator configured to isolate the plurality of pixels from each other. The pixel isolator may include a metal layer including a metal, a dielectric layer including a dielectric material, and a cavity layer not including any of the metal or the dielectric material. In the horizontal direction, the pixel isolator may include separate first regions in which the metal layer is located and second regions in which the dielectric layer is located. In the horizontal direction, the first regions may be diagonally arranged between adjacent pixels of the plurality of pixels.

According to some example embodiments of the inventive concepts, a solid-state image sensor may include a plurality of photoelectric converters arranged in a horizontal direction such that the plurality of photoelectric converters at least partially overlap each other in the horizontal direction, the plurality of photoelectric converters at least partially defining separate, respective pixels of a plurality of pixels in the solid-state image sensor. The solid-state image sensor may include a plurality of on-chip lenses, each separate on-chip lenses of the plurality of on-chip lenses on an upper surface of a separate photoelectric converter of the plurality of photoelectric converters in a lamination direction, the lamination direction perpendicular to the horizontal direction. The solid-state image sensor may include a wiring layer on a lower surface of each photoelectric converter of the plurality of photoelectric converters in the lamination direction. The solid-state image sensor may include a pixel isolator configured to isolate the plurality of pixels from each other. The pixel isolator may include a metal layer including a metal, a dielectric layer including a dielectric material, and a cavity layer not including any of the metal or the dielectric material. In the horizontal direction, the pixel isolator may include first regions in which the metal layer is located and second regions in which the dielectric layer is located. In the horizontal direction, the first regions may be diagonally arranged between adjacent pixels of the plurality of pixels. The metal layer may have a cross, rhombic, quadrangular, circular, or linear shape in the first regions. A length of the metal layer in the lamination direction may be greater than a wavelength of light that the plurality of photoelectric converters are configured to photoelectrically convert and may be less than or equal to a thickness of the plurality of photoelectric converters in the lamination direction. A boundary between the plurality of photoelectric converters and the pixel isolator may be at least partially covered by the dielectric layer. A length of the dielectric layer in the lamination direction may be greater than the length of the metal layer in the lamination direction. A light absorbance of the dielectric layer may be smaller than a light absorbance of the metal layer.

According to some example embodiments, a method may include manufacturing a solid-state image sensor based on providing a substrate; forming a pixel isolator, that isolates separate, respective regions of the substrate from each other in a horizontal direction such that the regions of the substrate at least partially overlap each other in a horizontal direction, based on forming a dielectric layer and a metal layer; forming a plurality of photoelectric converters in the substrate in separate, respective regions of the substrate such that the plurality of photoelectric converters are arranged in the horizontal direction such that the plurality of photoelectric converters at least partially overlap each other in the horizontal direction and at least partially define a plurality of pixels and further such that the pixel isolator isolates the plurality of pixels from each other; forming a wiring layer on one side of each photoelectric converter of the plurality of photoelectric converters in a lamination direction perpendicular to the horizontal direction, and forming a plurality of on-chip lenses on an opposite side of separate, respective photoelectric converters of the plurality of photoelectric converters in the lamination direction.

The dielectric layer may be formed based on forming a first trench into the substrate and at least partially filling the trench with a dielectric material.

The metal layer may be formed based on filling a second trench with a metal, the second trench at least partially defined by the dielectric layer.

The plurality of photoelectric converters may be formed based on injecting one or more dopants into the substrate in each of the separate, respective regions defined by the pixel isolator.

The method may further include forming a periodic structure between the plurality of photoelectric converters and at least one of the plurality of on-chip lenses or the wiring layer and having periodicity in the horizontal direction.

The method may include forming a planarization layer on the plurality of photoelectric converters, such that the plurality of on-chip lenses are formed on the planarization layer.

In some example embodiments, the method may further include manufacturing an electronic device using the solid-state image sensor.

### BRIEF DESCRIPTION OF THE DRAWINGS

Example embodiments will be more clearly understood from the following detailed description taken in conjunction with the accompanying drawings in which:

FIG. 1 is a plan view showing a pixel region including a plurality of pixels in a solid-state image sensor according to some example embodiments;

FIG. 2 is a front cross-sectional view showing the solid-state image sensor according to some example embodiments;

FIG. 3 is a partially enlarged view showing region A of FIG. 1;

FIG. 4 is a partially enlarged view showing region B of FIG. 3;

FIG. 5 is a diagram corresponding to FIG. 3 and illustrates a solid-state image sensor in Comparative Example 1;

FIG. 6 is a diagram corresponding to FIG. 3 and illustrates a solid-state image sensor in Comparative Example 2;

FIG. 7 is a diagram illustrating a mechanism by which color mixing occurs in the solid-state image sensor in Comparative Example 2;

FIG. 8 is a graph showing the numerical values of QE and MTF of the solid-state image sensors according to Comparative Example 1, Comparative Example 2, and some example embodiments;

FIG. 9 is a diagram corresponding to FIG. 3 and illustrates a solid-state image sensor of Modified Example 1;

FIG. 10 is a graph showing the numerical values of QE and MTF of the solid-state image sensors according to some example embodiments and Modified Example 1;

FIG. 11 is an image diagram illustrating an optical path in the solid-state image sensor according to Modified Example 1;

FIG. 12 is an image diagram illustrating an optical path in the solid-state image sensor according to some example embodiments;

FIG. 13 is an image diagram illustrating a state in which the metal layers absorb light in the solid-state image sensors according to some example embodiments and Modified Example 1;

FIG. 14 is a diagram corresponding to FIG. 3 and illustrates a solid-state image sensor according to Modified Example 2;

FIG. 15 is a diagram corresponding to FIG. 3 and illustrates a solid-state image sensor according to Modified Example 3;

FIG. 16 is a diagram corresponding to FIG. 3 and illustrates a solid-state image sensor according to Modified Example 4;

FIG. 17 is a diagram partially corresponding to FIG. 3 and illustrates a solid-state image sensor according to Modified Example 5;

FIG. 18 is a diagram partially corresponding to FIG. 3 and illustrates a solid-state image sensor according to Modified Example 6;

FIG. 19 is a schematic diagram of FIG. 2 and illustrates a solid-state image sensor according to Modified Example 7;

FIG. 20 is a schematic diagram of FIG. 2 and illustrates a solid-state image sensor according to Modified Example 8;

FIG. 21 is a schematic diagram of FIG. 2 and illustrates a solid-state image sensor according to Modified Example 9;

FIG. 22 is a schematic diagram of FIG. 2 and illustrates a solid-state image sensor according to Modified Example 10;

FIG. 23 is a diagram illustrating a solid-state image sensor according to Modified Example 11;

FIG. 24 is a diagram illustrating a solid-state image sensor according to Modified Example 12;

FIG. 25 illustrates a flowchart of a method according to some example embodiments; and

FIG. 26 is a schematic view illustrating an electronic device according to some example embodiments.

### DETAILED DESCRIPTION

Some example embodiments may have diverse changes and various forms, and thus, some example embodiments are illustrated in the drawings and described in detail. However, this is not intended to limit the example embodiments to some specific example embodiments. Also, example embodiments described below are only examples, and thus, various changes may be made from such example embodiments.

All examples or illustrative terms are only used to describe the technical idea in detail, and thus, the scope of the inventive concepts is not limited by these examples or illustrative terms unless limited by the claims.

As used herein, unless otherwise specified, a vertical direction may be defined as a Z direction, and a first horizontal direction and a second horizontal direction may each be defined as a horizontal direction perpendicular to the Z direction. The first horizontal direction may be referred to as an X direction and the second horizontal direction may be referred to as a Y direction. A vertical level may refer to a height level in the vertical direction Z. A horizontal width may refer to a length in the horizontal direction X and/or Y and a vertical length may refer to a length in the vertical direction Z. Also, two dimensions described in the inventive concepts may be defined by the first horizontal direction and the second horizontal direction. That is, the two-dimensional direction in the inventive concepts may be simply referred to as the horizontal direction.

As the inventive concepts allow for various changes and numerous various example embodiments, some example embodiments will be illustrated in the drawings and described in detail in the written description. However, this is not intended to limit the inventive concepts to particular modes of practice, and it is to be appreciated that all modifications, equivalents, and substitutes that do not depart from the spirit and technical scope of the inventive concepts are encompassed in the inventive concepts. In describing the inventive concepts, when it is determined that the specific description of the known related art unnecessarily obscures the gist of the inventive concepts, the detailed description thereof will be omitted.

A portion of a layer, film, region, plate, or the like described as being “on” or “above” another portion as used herein, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

In order to clearly explain the present inventive concepts in the drawings, parts that are not related to the description are omitted, and similar parts are given similar reference numerals throughout the specification. In the methods described herein, the order of operations may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

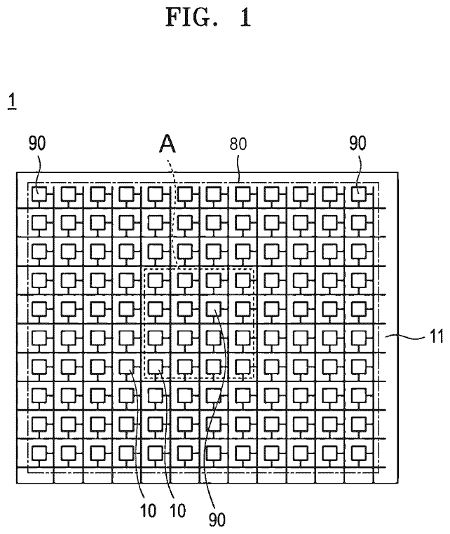

Hereinafter, some example embodiments are described with reference to FIGS. 1 to 4. In addition, the scale of dimensions in the drawings may be exaggerated for convenience of description and may differ from the actual scale.

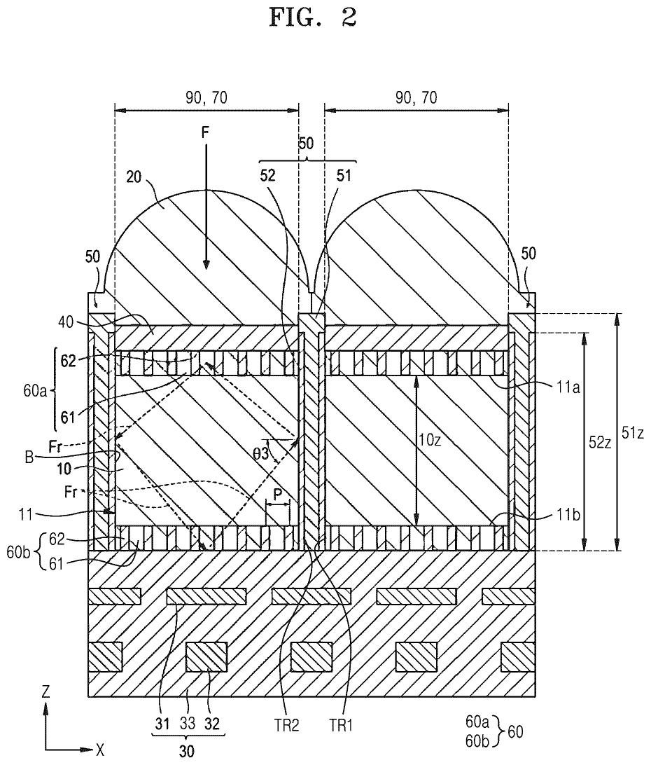

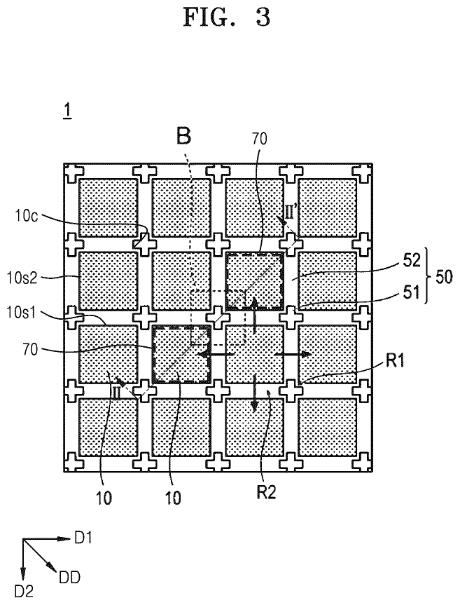

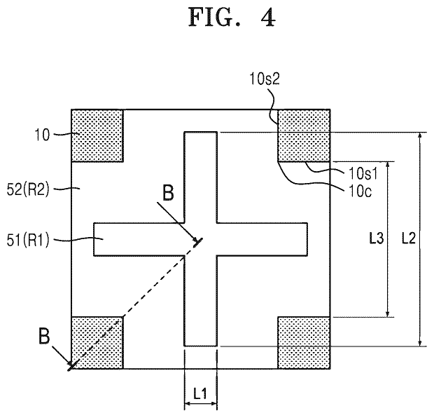

FIG. 1 is a plan view showing a pixel region including a plurality of pixels 90 in a solid-state image sensor 1 according to some example embodiments. FIG. 2 is a front cross-sectional view showing the solid-state image sensor 1 according to some example embodiments. FIG. 3 is a partially enlarged view showing region A of FIG. 1. FIG. 4 is a partially enlarged view showing region B of FIG. 3. FIG. 2 is a cross-sectional view along view line II-II′ in FIG. 3.

The solid-state image sensor 1 according to some example embodiments includes a solid-state image sensor provided as a complementary metal oxide semiconductor (CMOS).

It is desirable for the solid-state image sensor 1 to exhibit a high quantum efficiency (QE). The QE represents the ratio of the number of generated electrons to the number of incident photons.

It is desirable for a solid-state image sensor to exhibit a high modulation transfer function (MTF), which may be used as a criterion for evaluating resolution. The MTF is obtained by comparing the QE of a first pixel with the QE of an adjacent second pixel, which is caused by light leaking from that first pixel to the adjacent second pixel.

The solid-state image sensor 1 includes a plurality of pixels 90 that form (e.g., define) a pixel region 80 as shown in FIG. 1. The solid-state image sensor 1, as shown in FIGS. 1 and 2, has a plurality of photoelectric converters 10 arranged in two dimensions, a plurality of on-chip lenses 20 installed above the plurality of photoelectric converters 10 (e.g., on one side of separate, respective photoelectric converters 10 of the plurality of photoelectric converters 10 in a lamination direction, the lamination direction perpendicular to the horizontal direction), a wiring layer 30 installed below the plurality of photoelectric converters 10, a pixel isolator 50 separating the plurality of pixels 90 from each other (e.g., isolating adjacent pixels 90 of the plurality of pixels 90 from each other), and a periodic structure 60 installed between the plurality of photoelectric converters 10 and at least one of the plurality of on-chip lenses 20 or the wiring layer 30 (e.g., a plurality of periodic structures 60, each periodic structure 60 between a separate photoelectric converter 10 and at least one of a separate on-chip lens 20 or the wiring layer 30).

The photoelectric converters 10 are installed in plurality in a substrate 11, as shown in FIG. 1. The substrate 11 may include, for example, a semiconductor substrate, such as a silicon (Si) substrate. The lower surface of the substrate 11 corresponds to the outer surface of the substrate 11 (e.g., “frontside 11b”), and the upper surface of the substrate 11 corresponds to the back surface (e.g., “backside 11a”) of the substrate 11. As shown, the plurality of photoelectric converters 10 arranged in a horizontal direction (X direction) such that the plurality of photoelectric converters 10 at least partially overlap each other in the horizontal direction (X direction), and the plurality of photoelectric converters 10 at least partially define separate, respective pixels 90 of the plurality of pixels 90 in the solid-state image sensor 1 (e.g., define at least the boundaries of the pixels 90 in the horizontal direction). As shown, the photoelectric converters 10 may be in separate, respective regions 70 of the substrate 11 that are isolated from each other by the pixel isolator 50 and which at least partially define the separate, respective pixels 90 that are isolated from each other by the pixel isolator 50.

In some example embodiments, the solid-state image sensor 1 is in a so-called backside-illuminated form, and thus, the on-chip lenses 20 are installed on the backside 11a of the substrate 11. The backside 11a of the substrate 11 may correspond to a surface of the substrate 11, to which the light is incident. Also, the wiring layer 30 is installed on the outside of the substrate 11. The thickness of the substrate 11 is, for example, from about 1 μm to about 10 μm. As shown, the on-chip lenses 20 may be on one side (e.g., backside 11a) of separate, respective photoelectric converters 10 of the plurality of photoelectric converters 10 in a lamination direction (e.g., Z direction), the lamination direction perpendicular to the horizontal direction (e.g., perpendicular to the backside 11a), and the wiring layer 30 may be on another, opposite side (e.g., frontside 11b) of each photoelectric converter 10 of the plurality of photoelectric converters 10 in the lamination direction (Z direction).

A photoelectric converter 10 is installed for each of the pixels 90 in the substrate 11. For example, as shown in at least FIGS. 1 and 2, each separate photoelectric converter 10 of the plurality of photoelectric converters may define the horizontal boundaries of a separate pixel 90 of the plurality of pixels 90. Each photoelectric converter 10 includes a p-type semiconductor region and an n-type semiconductor region. In each photoelectric converter 10, a photodiode is formed by a p-n junction between the p-type semiconductor region and the n-type semiconductor region, and the photodiode converts light into electric charges. Each photoelectric converter 10 may be defined by a p-type semiconductor region of the substrate 11 that further includes a p-type dopant and an n-type semiconductor region of the substrate 11 that further includes an n-type dopant.

Each photoelectric converter 10 receives light incident onto an on-chip lens 20, generates signal charges according to the amount (e.g., intensity) of received light (e.g., based on photoelectrically converting the received light into electrical signal charges), and accumulates the generated signal charges in the n-type semiconductor region. The photoelectric converters 10 may be configured to photoelectrically convert light of any wavelength, including for example light in any wavelength in the entire visible spectrum and in some example embodiments including at least light in the infrared and/or visible spectrum. The photoelectric converter 10 may be configured to photoelectrically convert light of a particular limited wavelength in the visible spectrum, including for example red, blue, and/or green light.

The photoelectric converters 10, which are adjacent to each other (e.g., adjacent to each other in the horizontal direction X), are separated (e.g., isolated) by a pixel isolator 50 provided with a metal layer 51 and a dielectric layer 52, as shown in FIG. 2, such that the pixel isolator 50 may isolate the plurality of pixels 90 (at least partially defined by the polarity of photoelectric converters 10) from each other (e.g., isolate the plurality of pixels 90 from each other in at least a horizontal direction X). Therefore, it is difficult for signal charges to leak from one pixel 90 and enter nearby (e.g., adjacent) pixels 90. Therefore, when signal charges exceeding the saturated quantity of charges are generated, the leakage of signal charges from one photoelectric converter 10 to the adjacent photoelectric converter 10 may be reduced, minimized, or prevented. This may suppress (e.g., reduce, minimize, or prevent) color mixing between pixels, thereby improving the MTF and thereby improving the image sensing performance and/or image capture/generating performance of the image sensor 1.

In addition, a fixed charge layer may be installed between adjacent photoelectric converters 10. The fixed charge layer may reduce, minimize, or prevent the generation of dark current, thereby reducing noise in the images generated based on signals generated by the image sensor 1, and thereby improving the image sensing performance and/or image capture/generating performance of the image sensor 1.

The materials that constitute (e.g., comprise) the fixed charge layer may include, for example, an oxide layer or nitride layer including at least one metal element among hafnium (Hf), aluminum (Al), zirconium (Zr), tantalum (Ta), and titanium (Ti). The methods of forming a fixed charge layer include, for example, chemical vapor deposition (CVD), sputtering, and atomic layer deposition (ALD), or the like.

An on-chip lens 20 is formed for each of the pixels 90. For example, the plurality of on-chip lenses 20 may be on separate, respective pixels 90 of the plurality of pixels 90. For example, the plurality of on-chip lenses 20 may be on separate, respective photoelectric converters 10 of the plurality of photoelectric converters 10. Each on-chip lens 20 collects incident light. The light collected by the on-chip lens 20 is incident onto a respective photoelectric converter 10 that the on-chip lens 20 is on (e.g., in a lamination direction Z perpendicular to the backside 11a).

In addition, it is desirable to install a light-blocking layer, a planarization layer, or the like between the on-chip lens 20 and the photoelectric converter 10. For example, the solid-state image sensor 1 may include a planarization layer 40 between the plurality of photoelectric converters 10 and the plurality of on-chip lenses 20 in the lamination direction (Z direction). The planarization layer 40 may comprise, for example, any one or more of silicon (Si), silicon dioxide (SiO₂), silicon nitride (SiN), aluminum oxide (AlO), tantalum oxide (TaO), titanium nitride (TiN), or titanium oxide (TiO).

The wiring layer 30 includes a plurality of wiring layers, which are provided in a lamination direction Z shown in FIG. 2 (which may be perpendicular to the backside 11a). The wiring layers 30 may include a first wiring layer 31 and a second wiring layer 32 and a third wiring layer 33. In addition, the number (quantity) of wiring layers installed in one solid-state image sensor 1, the arrangement of wiring layers in the two-dimensional direction, and the cross-sectional shape of wiring layers in the lamination direction may not be specifically limited but arbitrarily changed. In some example embodiments, the first and second wiring layers 32 may comprise a metal and/or conductive material (e.g., polysilicon, tungsten, aluminum, copper, or any conductive metal material), and the third wiring layer(s) 33 may include silicon, polysilicon, any one or more of silicon (Si), silicon dioxide (SiO₂), silicon nitride (SiN), aluminum oxide (AlO), tantalum oxide (TaO), titanium nitride (TiN), or titanium oxide (TiO), any combination thereof, or the like.

The first wiring layer 31 and the second wiring layer 32 extract, as pixel signals, the signal charges generated and accumulated by one or more of the photoelectric converters 10. The first wiring layer 31 and the second wiring layer 32 output (“transmit”) the extracted pixel signals.

The pixel isolator 50 has, as shown in FIG. 2, the metal layer 51 including metal and the dielectric layer 52 including a dielectric material. As shown in FIG. 2, the metal layer 51 is fitted into the dielectric layer 52. In some example embodiments, a boundary between the plurality of photoelectric converters 10 and the pixel isolator 50 is at least partially covered (e.g., in a horizontal direction X and/or a lamination direction Z) by the dielectric layer 52. The light absorption rate (e.g., light absorbance) of the dielectric layer 52 may be less (e.g., smaller) than a light absorption rate (e.g., light absorbance) of the metal layer 51. In some example embodiments, the dielectric layer 52 occupies a trench TR1 in the substrate 11 in the lamination direction Z and the metal layer 51 occupies a trench TR2 that is at least partially defined by inner surfaces of the dielectric layer 52 (e.g., a trench formed in the dielectric layer 52 and/or a trench that represents a portion of trench TR2 that is not occupied by the dielectric layer 52).

The materials used to constitute (e.g., comprise) the metal layer 51 may include a metal which may include, for example, any one or more of tungsten, aluminum, or copper.

The materials used to constitute (e.g., comprise) the dielectric layer 52 may include a dielectric material which may include, for example, any one or more of silicon dioxide (SiO₂), silicon nitride (SiN), aluminum oxide (AlO), tantalum oxide (TaO), titanium nitride (TiN), or titanium oxide (TiO).

As shown in FIG. 3, in the two-dimensional direction (the horizontal direction X), which is perpendicular to the lamination direction Z of the photoelectric converters 10 (e.g., is parallel to the backside 11a), the pixel isolator 50 has a first region R1 in which the metal layer 51 is formed and a second region R2 in which the dielectric layer 52 is formed. The metal layer 51 may define the first region R1 and the dielectric layer 52 may define the second region R2. For example, the pixel isolator 50 may include separate first regions R1 that are defined by the metal layer 51 and second regions R2 defined by at least the dielectric layer 52.

In some example embodiments, first regions R1 are formed, in the pixel isolator 50, at locations of each pixel 90 in a diagonal direction (e.g., between opposing vertices and/or corners 10c of diagonally-adjacent pixels 90 in a diagonal direction DD that is diagonal to respective first and second horizontal directions D1 and D2 which are parallel to sides 10s1 and 10s2, respectively, of the photoelectric converters 10), as shown in FIG. 3. The diagonal direction DD here represents the four directions of right up, left up, right down, and left down as viewed from the pixel 90 of FIG. 1.

The length (e.g., thickness) in the lamination direction Z of the metal layer 51 (51z) and the dielectric layer 52 (52z) is greater than the wavelength of light received by the photoelectric converter 10 and is approximately equal (e.g., equal or substantially equal) to or greater than the thickness in the lamination direction Z of the photoelectric converter 10 (10z), as shown in FIG. 2. However, example embodiments are not limited thereto. For example, as shown in FIG. 2, the thickness 52z of the dielectric layer 52 in the lamination direction Z may be equal to or greater than the thickness 10z of the photoelectric converter 10 in the lamination direction Z, and the thickness 51z in the lamination direction Z of the metal layer 51 may be greater than both the thickness 52z of the dielectric layer 52 and the thickness 10z of the photoelectric converter 10 in the lamination direction Z, while thicknesses 51z and 52z may each be greater than the wavelength of light that the photoelectric converter 10 is configured to photoelectrically convert. In some example embodiments, the photoelectric converters 10 may be configured to photoelectrically convert light of the entire visible spectrum (or at least red light), such that the length (e.g., thickness) in the lamination direction Z of the metal layer 51 (51z) and the dielectric layer 52 (52z) is greater than a longest wavelength of the visible spectrum, for example greater than 750 nm. In some example embodiments, the photoelectric converters 10 may be configured to photoelectrically convert light of at least the near-infrared spectrum, such that the length (e.g., thickness) in the lamination direction Z of the metal layer 51 (51z) and the dielectric layer 52 (52z) is greater than a longest wavelength of the near-infrared spectrum, for example greater than 1400 nm.

The volume of the metal layer 51 is set according to the desired QE. That is, the volume of the metal layer 51 may correspond to the QE. For example, a volume of the metal layer 51 may at least partially define a QE of the solid-state image sensor 1. When the metal layer 51 has a large volume, the MTF improves while the QE degrades. In some example embodiments, when the metal layer 51 has a small volume, the MTF degrades while the QE improves.

In a plan view, the metal layer 51 has a cross shape as shown in FIG. 4. Referring to FIG. 4, a core width L1 of the metal layer 51 in a cross shape is, for example, 80 nm, a total length L2 of the metal layer 51 in a cross shape is, for example, 800 nm, and a length L3 of the pixel isolator 50 is, for example, 480 nm.

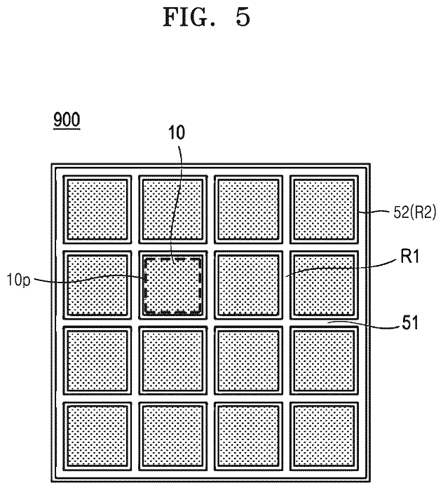

Hereinafter, the configurations of solid-state image sensors in Comparative Examples 1 and 2 are described with reference to FIGS. 5, 6, and 7.

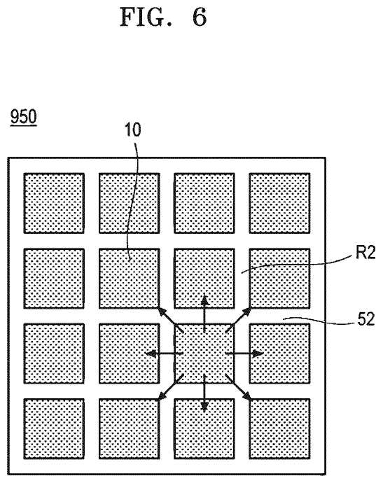

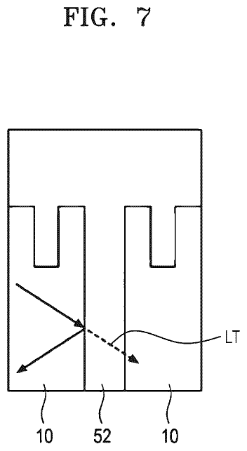

FIG. 5 is a diagram corresponding to FIG. 3 and illustrates a solid-state image sensor 900 in Comparative Example 1. FIG. 6 is a diagram corresponding to FIG. 3 and illustrates a solid-state image sensor 950 in Comparative Example 2. FIG. 7 is a diagram illustrating a mechanism by which color mixing occurs in the solid-state image sensor 950 in Comparative Example 2.

As shown in FIG. 5, the solid-state image sensor 900 in Comparative Example 1, unlike the solid-state image sensor 1 according to some example embodiments, has (e.g., defines) a first region R1, which is a metal layer 51 (e.g., defined by a metal layer 51), continuously formed (e.g., as a continuous and single, unitary piece of material) around the outer perimeter 10p of the photoelectric converter 10 in a plan view of a pixel isolator. In some example embodiments, as shown in FIG. 6, the solid-state image sensor 950 in Comparative Example 2, unlike the solid-state image sensor 1 according to some example embodiments, includes only a second region R2, which is a dielectric layer 52 (e.g., is defined by at least the dielectric layer 52), in a plan view of a pixel isolator 50.

In the solid-state image sensor 900 of Comparative Example 1, the photoelectric converter 10 is covered by a first region R1 that is a metal layer 51 (e.g., is defined by the metal layer 51), which prevents light from leaking into adjacent pixels, or reduces or minimizes such leakage, thereby reducing, minimizing, or preventing color mixing and increasing or maximizing the MTF. On the other hand, the metal layer has a significant light absorption (e.g., light absorbance), which degrades the QE.

In some example embodiments, in the solid-state image sensor 950 of Comparative Example 2, the pixel isolator includes only a second region R2 that is a dielectric layer 52 (e.g., is defined by the dielectric layer 52), thereby reducing, minimizing, or preventing the absorption of light and increasing the QE. Also, since light may travel through the dielectric layer 52, light LT may travel to adjacent pixels, as shown by the dashed arrows in FIG. 7, causing color mixing and degrading the MTF.

In contrast, in the solid-state image sensor 1 according to some example embodiments, the pixel isolator 50 has the first region R1 in which the metal layer 51 is formed and the second region R2 in which the dielectric layer 52 is formed. As a result, light transmission and absorption that causes color mixing may be prevented in a balanced manner, enabling the MTF to be greater than or equal to a desired value while the QE is greater than or equal to a desired value.

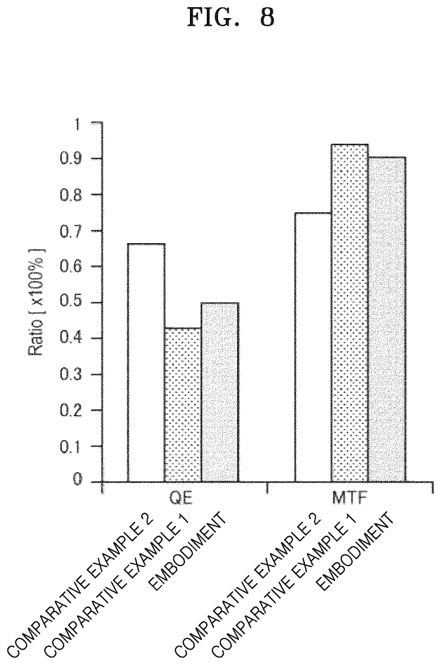

The simulated results of the numerical values of QE and MTF of the solid-state image sensor 1 according to some example embodiments, the solid-state image sensor 900 according to Comparative Example 1, and the solid-state image sensor 950 according to Comparative Example 2 are described with reference to FIG. 8.

FIG. 8 is a graph showing the numerical values of QE and MTF of the solid-state image sensors according to Comparative Example 1, Comparative Example 2, and some example embodiments (“Embodiment”) (e.g., the example embodiments shown in FIGS. 1 to 4).

As can be seen from FIG. 8, the solid-state image sensor 1 according to some example embodiments (“Embodiment”) (e.g., the example embodiments shown in FIGS. 1 to 4) has a QE higher than that of Comparative Example 1 and an MTF higher than that of Comparative Example 2, and may achieve a balance between the QE and the MTF. Also, there is a significant difference in the values of QE and MTF between the solid-state image sensor 900 of Comparative Example 1 and the solid-state image sensor 950 of Comparative Example 2, and this difference may not be reduced by the configurations of Comparative Example 1 and Comparative Example 2.

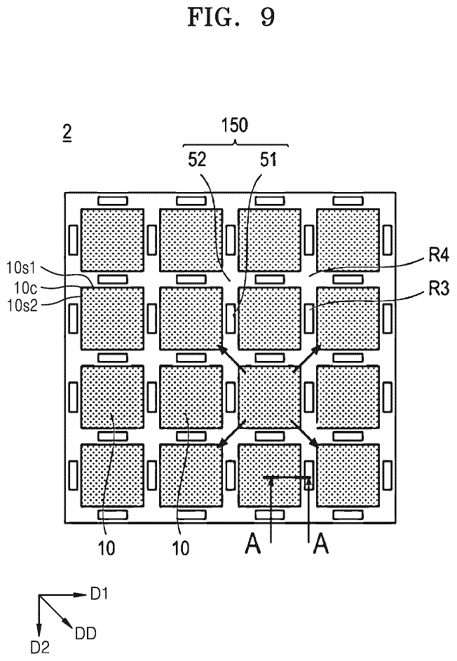

Next, the configuration of a pixel isolator 150 of a solid-state image sensor 2 according to Modified Example 1 is described with reference to FIG. 9.

FIG. 9 is a diagram corresponding to FIG. 3 and illustrates a solid-state image sensor 2 of Modified Example 1.

The pixel isolator 150 of the solid-state image sensor 2 according to Modified Example 1 has a first region R3 in which a metal layer 51 is formed and a second region R4 in which a dielectric layer 52 is formed, as shown in FIG. 9.

The first regions R3 (including metal layer 51) are formed, in the pixel isolator 150, between photoelectric converters 10 adjacent to each other in the left-right direction and the up-down direction (e.g., diagonal direction DD), in a plan view as shown in FIG. 9. The second regions R4 (including dielectric layer 52) are formed, in the pixel isolator 150, in the diagonal direction DD described above.

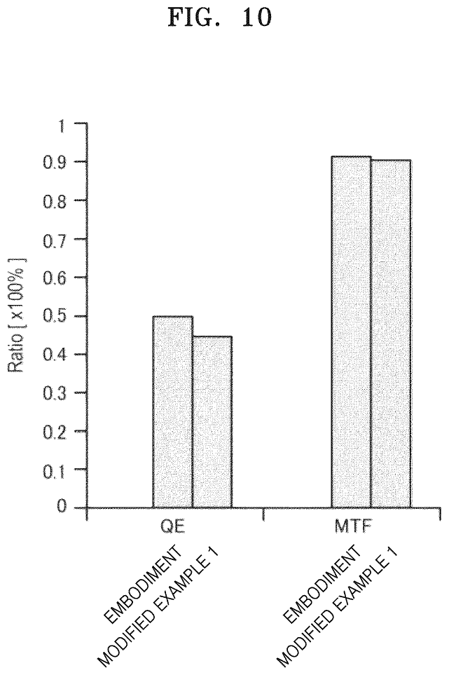

Next, the numerical values of QE and MTF of the solid-state image sensor 1 according to some example embodiments and the solid-state image sensor 2 according to Modified Example 1 are described with reference to FIGS. 10 to 13.

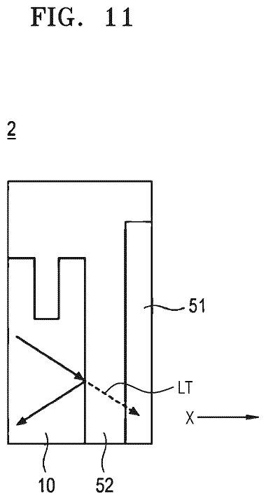

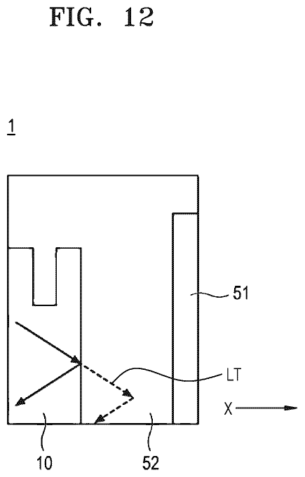

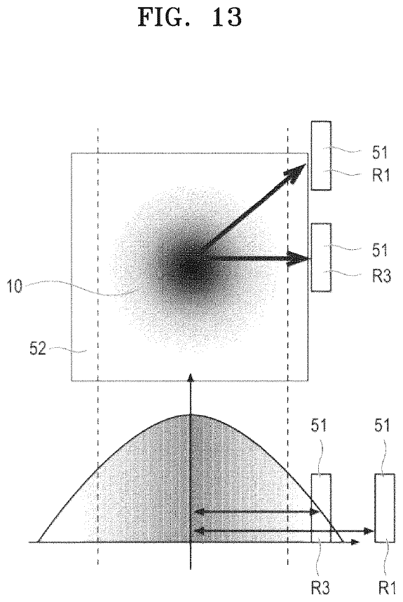

FIG. 10 is a graph showing the numerical values of QE and MTF of the solid-state image sensors according to some example embodiments (“Embodiment”) and Modified Example 1. FIG. 11 is an image diagram illustrating an optical path in the solid-state image sensor 2 according to Modified Example 1. FIG. 12 is an image diagram illustrating an optical path in the solid-state image sensor 1 according to some example embodiments. FIG. 13 is an image diagram illustrating a state in which the metal layers 51 absorb light in the solid-state image sensors according to some example embodiments and Modified Example 1.

The solid-state image sensor 1 according to some example embodiments is described with reference to FIGS. 11, 12, and 13, with comparison to the solid-state image sensor 2 according to Modified Example 1.

FIG. 11 corresponds to Modified Example 1 and shows a schematic cross-sectional view in the vicinity of the photoelectric converter 10 and the first region R3 of FIG. 9. FIG. 11 is a cross-sectional view of the solid-state image sensor 2 taken along line A-A of FIG. 9. FIG. 12 corresponds to some example embodiments and shows a schematic cross-sectional view in the vicinity of the photoelectric converter 10 and the first region R1 of FIG. 3. FIG. 12 is a cross-sectional view of the solid-state image sensor 1 taken along line B-B of FIG. 4. FIG. 13 illustrates the intensities (distributions) of incident light at the locations of the first region R1 and the first region R3 of the pixel 90.

The distance from the center of the photoelectric converter 10 to the metal layer 51 (the first region R3) in the horizontal direction X (e.g., D1 and/or D2 and/or DD) in Modified Example 1 is less than the distance from the center of the photoelectric converter 10 to the metal layer 51 (the first region R1) in the horizontal direction X (e.g., D1 and/or D2 and/or DD) in the solid-state image sensor 1 according to some example embodiments. In some example embodiments (e.g., the example embodiments shown in at least FIGS. 1 to 4), the width (the layer thickness) of the dielectric layer 52 in the left-right direction in Modified Example 1 shown in FIG. 11 is less than the width (the layer thickness) of the dielectric layer 52 in the left-right direction in some example embodiments shown in FIG. 12. Thus, the light LT that has escaped from the photoelectric converter 10 and entered the dielectric layer 52 reaches the metal layer 51 and is then absorbed by the metal layer 51, and thus, the QE is slightly degraded by the amount of absorbed light.

On the other hand, the distance from the center of the photoelectric converter 10 to the metal layer 51 (the first region R1) in the horizontal direction X (e.g., D1 and/or D2 and/or DD) in the solid-state image sensor 1 according to some example embodiments (e.g., the example embodiments shown in at least FIGS. 1 to 4) is greater than the distance from the center of the photoelectric converter 10 to the metal layer 51 (the first region R3) in the horizontal direction X (e.g., D1 and/or D2 and/or DD) in the solid-state image sensor 2 according to Modified Example 1. Furthermore, in some example embodiments (e.g., the example embodiments shown in at least FIGS. 1 to 4), the width (the layer thickness), in the left-right direction, of the dielectric layer 52 according to some example embodiments is greater than the width (the layer thickness), in the left-right direction, of the dielectric layer 52 according to Modified Example 1. Accordingly, the light LT that has escaped from the photoelectric converter 10 and entered the dielectric layer 52 is difficult to reach the metal layer 51. Therefore, the absorption of light into the metal layer 51 is reduced, minimized, or prevented, which may suppress the degradation of the QE. For example, in some example embodiments and Modified Example 1, the metal layer 51 may block stray light at any location, thereby suppressing color mixing and improving the MTF.

As a result, as shown in FIG. 10, the QE and MTF of the solid-state image sensor 1 according to some example embodiments (“Embodiment”) (e.g., the example embodiments shown in at least FIGS. 1 to 4) exhibit higher values than the solid-state image sensor 2 according to Modified Example 1. From the above, the configuration in which the metal layers 51 are formed diagonally (the solid-state image sensor 1 according to some example embodiments, including the example embodiments shown in FIGS. 1 to 4) may have the QE and MTF exceeding certain values, compared to the configuration in which the metal layers 51 are formed at points adjacent to each other on the sides of the pixels 90 (the solid-state image sensor 2 according to Modified Example 1). Also, the inventive concepts also include the solid-state image sensor 2 according to Modified Example 1.

Next, the configuration of the periodic structure 60 is described with reference to FIG. 2. The periodic structure 60 is formed in a certain range in the lamination direction Z of the photoelectric converter 10. In some example embodiments, the periodic structure 60 includes regions (portions) in which first and second layers 61 and 62 are alternately arranged in a two-dimensional direction (e.g., horizontal direction X), to the extent that the second layer 62 extends in the lamination direction (Z) of the photoelectric converter 10 as shown in FIG. 2.

As shown in FIG. 2, in some example embodiments the periodic structure 60 may be defined by the first and second layers 61 and 62 at one or both of the backside 11a or the frontside 11b of the substrate 11. For example, as shown in FIG. 2, in some example embodiments the periodic structure 60 may include a first portion 60a and/or a second portion 60b. The first portion 60a of the periodic structure 60 may be at least partially defined by first and second layers 61 and 62 on the photoelectric converters 10 at the backside 11a so as to be between the photoelectric converters 10 and the planarization layer 40. The second portion 60b of the periodic structure 60 may be at least partially defined by first and second layers 61 and 62 on the photoelectric converters 10 at the backside 11a so as to be between the photoelectric converters 10 and the wiring layer 30. In some example embodiments, one of the first and second portions 60a and 60b may be omitted. In some example embodiments, the periodic structure 60 (e.g., both the first and second portions 60a and 60b) may be omitted.

The periodic structure 60 has periodicity in a two-dimensional direction perpendicular to the lamination direction (the planar direction, the horizontal direction X, etc.), as shown in FIG. 2. The periodic structure 60 has the first layer 61 and the second layer 62 that has a lower refractive index of light than the first layer 61, as shown in FIG. 2. The first layer 61 and the second layer 62 are provided in plurality.

In the periodic structure 60 (e.g., in each of the first and second portions 60a and 60b), the first layers 61 and the second layers 62 are arranged in a regular manner so as to form (e.g., define) a period P in the two-dimensional direction.

The difference in the refractive index of light between the first layer 61 and the second layer 62 may be defined, for example, by the characteristics (permittivity) of the materials constituting the first and second layers 61 and 62.

The materials constituting the first and second layers 61 and 62, which may achieve the desired difference in refractive index of light, may be selected, for example, as a combination of the following materials.

The material used to constitute the first layer 61 may include, for example, any one of silicon (Si), germanium (Ge), or indium gallium arsenide (InGaAs).

When the first layer 61 includes any one of the materials described above, the material used to constitute the second layer 62 may include, for example, any one or more of silicon dioxide (SiO₂), silicon nitride (SiN), aluminum oxide (AlO), tantalum oxide (TaO), titanium nitride (TiN), or titanium oxide (TiO).

The effect of the arrangement of the periodic structure 60 in this manner is described (enhancement of QE by diffracted light).

In the periodic structure 60, the first layers 61 and the second layers 62 are arranged in a regular manner so as to form (e.g., define) the period P in the two-dimensional direction. As shown in FIG. 2, incident light F is incident onto the periodic structure 60 from above the photoelectric converter 10.

The periodic structure 60 generates diffracted light Fr based on diffracting light incident on the periodic structure 60 (e.g., light incident on the periodic structure 60 from an interior of the photoelectric converters 10). The periodic structure 60 exhibits a constant period P in the two-dimensional direction. Therefore, the periodic structure 60 may generate the diffracted light Fr at each region in the two-dimensional direction (X) according to the period P.

As shown in FIG. 2, the diffracted light Fr generated by the periodic structure 60 travels through the inside of the photoelectric converter 10 in an inclined direction (e.g., a direction between and different from both the lamination direction Z and the horizontal direction X), rather than traveling the shortest straight-line distance from the top to the bottom inside the photoelectric converter 10. Therefore, compared to the case in which diffracted light Fr is not generated, the pixel 90 may increase the length of the optical path along which the photoelectric converter 10 converts light to electric charges.

In the pixel 90, the length of the optical path along which the photoelectric converter 10 converts light to electric charges is increased, and thus, the amount of light absorbed by the photoelectric converter 10 is increased. As a result, the pixel 90 may exhibit a high QE in the photoelectric converter 10 and thereby improving the image sensing performance and/or image capture/generating performance of the image sensor 1.

The period P of the periodic structure 60 is configured to have a certain size based on the wavelength and angle of incidence of the light received by the photoelectric converter 10 (e.g., the wavelength and/or angle of incidence of light that the photoelectric converter 10 is configured to photoelectrically convert, for example any wavelength of the visible spectrum). In some example embodiments, the period P of the periodic structure 60 may correspond to the wavelength and the angle of incidence of the light received by the photoelectric converter 10.

In some example embodiments, the period P of the periodic structure 60 may be formed to a length less than the wavelength of the light to be received (e.g., light that the photoelectric converters 10 are configured to photoelectrically convert) (e.g., smaller than a shortest wavelength of visible light, for example smaller than 380 nm) and may also be formed to a length that may generate the diffracted light Fr in the photoelectric converter 10.

As shown in FIG. 2, the photoelectric converter 10 is at least partially covered (e.g., in a horizontal direction X) by the dielectric layer 52 that has a lower refractive index of light than the first layer 61.

The dielectric layer 52 may cover the photoelectric converter 10 at three locations, for example, the bottom location and the left-right locations with respect to the lamination direction Z as shown in FIG. 2. However, the location of the dielectric layer 52 is not particularly limited as long as the dielectric layer 52 may exhibit the effect of totally reflecting diffracted light, which is described below.

The period P of the periodic structure 60 may have a length such that the total reflection of the diffracted light Fr generated by the photoelectric converter 10 may be formed between the photoelectric converter 10 and the dielectric layer 52.

The pixel 90 may totally reflect the diffracted light Fr generated inside the photoelectric converter 10 from the dielectric layer 52, thereby increasing the length of the optical path of the diffracted light Fr inside the photoelectric converter 10. Therefore, the pixel 90 may further increase the amount of light absorbed by the photoelectric converter 10. The period P of the periodic structure 60 may have a length (e.g., magnitude) that configures the periodic structure 60 to totally reflect diffracted light Fr at a boundary B between at least one photoelectric converter 10 and the pixel isolator 50.

When the period P of the periodic structure 60 has a length of, for example, 600 nm, a condition in which the dielectric layer 52 totally reflects the diffracted light Fr is that the angle of incidence θ₃ shown in FIG. 2 (the angle of incidence θ₃ for the dielectric layer 52)≥23.7°. This condition may be derived by substituting the refractive index of the first layer 61 and the refractive index of the dielectric layer 52 into the well-known Snell's law.

However, the inventive concepts are not limited to some example embodiments (e.g., the example embodiments shown in FIGS. 1 to 4) and Modified Example 1 described above, and may be modified in other forms.

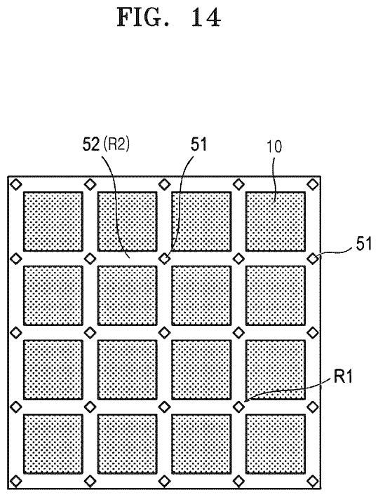

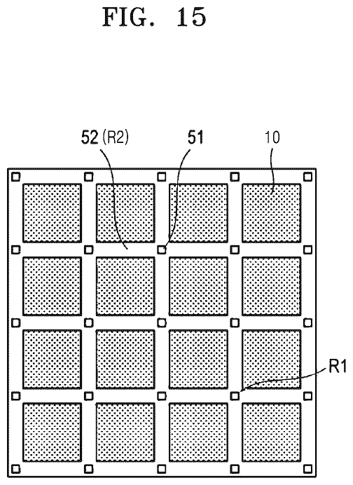

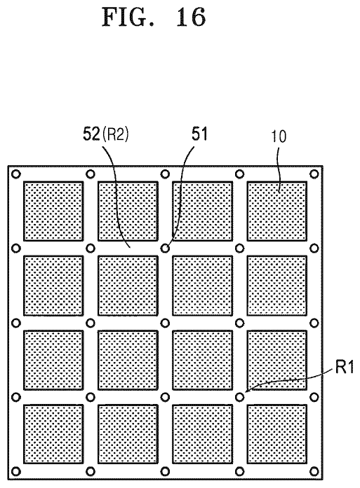

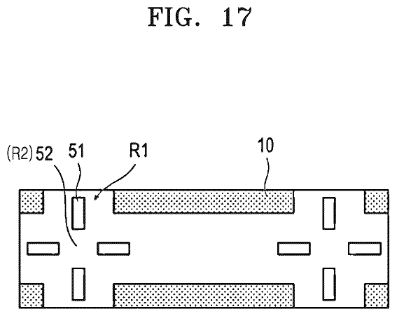

FIG. 14 is a diagram corresponding to FIG. 3 and illustrates a solid-state image sensor according to Modified Example 2. FIG. 15 is a diagram corresponding to FIG. 3 and illustrates a solid-state image sensor according to Modified Example 3. FIG. 16 is a diagram corresponding to FIG. 3 and illustrates a solid-state image sensor according to Modified Example 4. FIG. 17 is a diagram partially corresponding to FIG. 3 and illustrates a solid-state image sensor according to Modified Example 5.

For example, in some example embodiments described above, the first region R1 in which the metal layer 51 is formed has a cross shape. However, the first region R1 in which the metal layer 51 is formed may have a rhombic shape, as shown in FIG. 14. In some example embodiments, the first region R1 in which the metal layer 51 is formed may have a rectangular shape, as shown in FIG. 15.

In some example embodiments, the first region R1 in which the metal layer 51 is formed may have a circular shape, as shown in FIG. 16. In some example embodiments, although not illustrated, the first region R1 in which the metal layer 51 is formed may have a line shape. In some example embodiments, the first region R1 in which the metal layer 51 is formed may have a shape in which the central region of the cross shape is replaced by a dielectric layer 52, as shown in FIG. 17. The configuration of FIG. 17 reduces the volume of the metal layer 51 and may thus improve the QE and thereby improve the image sensing performance and/or image capture/generating performance of the solid-state image sensor.

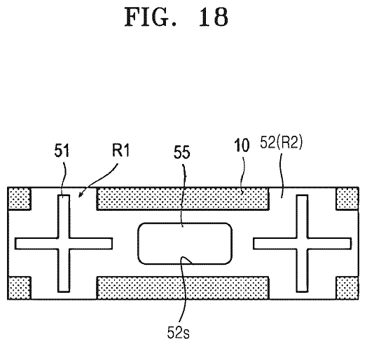

FIG. 18 is a diagram partially corresponding to FIG. 3 and illustrates a solid-state image sensor according to Modified Example 6.

As shown in FIG. 18, an air layer 55 (also referred to herein as a cavity layer) may be formed between first regions R1 in which metal layers 51 are formed. For example, the air layer 55 may be defined by one or more inner surfaces 52s of the dielectric layer 52. The air layer 55 may exclude (e.g., may not include) any of the metal layer 51 or the dielectric layer 52. According to this configuration, the air layer 55 having a low refractive index is formed so that total reflection is more likely to occur in the air layer 55. Accordingly, the color mixing may be reduced and the MTF may be improved.

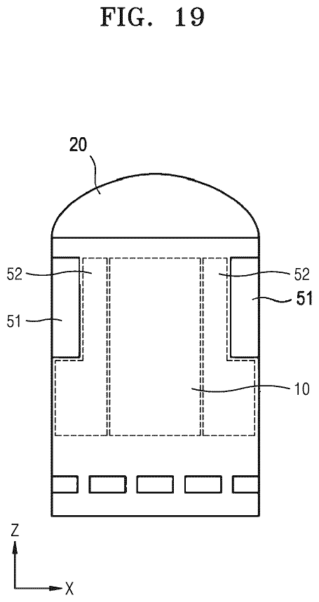

FIG. 19 is a schematic diagram of FIG. 2 and illustrates a solid-state image sensor according to Modified Example 7. In some example embodiments described above, the length of each of the metal layer 51 and the dielectric layer 52 in the lamination direction (Z direction) is approximately equal to the thickness of the photoelectric converter 10 in the lamination direction (Z direction). However, as shown in FIG. 19, in some example embodiments the length of a dielectric layer 52 in the lamination direction is approximately equal to the length of a photoelectric converter 10 in the lamination direction, and the length of a metal layer 51 in the lamination direction is approximately half of the length of the photoelectric converter 10 in the lamination direction. In addition, as shown in FIG. 19), the upper end of the metal layer 51 may be configured to be aligned (e.g., coplanar) with the upper end of the photoelectric converter 10.

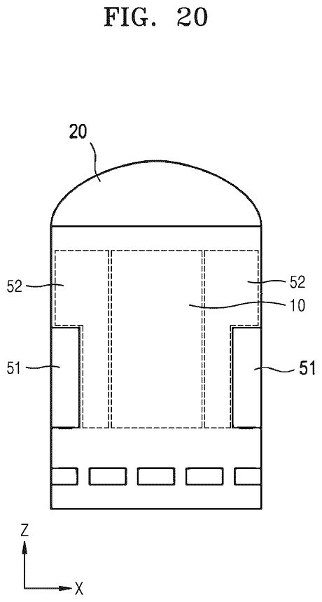

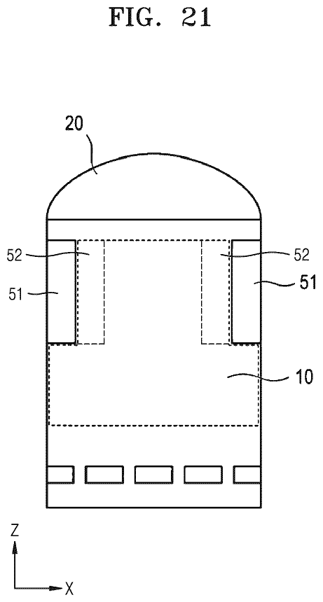

FIG. 20 is a schematic diagram of FIG. 2 and illustrates a solid-state image sensor according to Modified Example 8. FIG. 21 is a schematic diagram of FIG. 2 and illustrates a solid-state image sensor according to Modified Example 9.

As shown in FIG. 20, the length of a dielectric layer 52 in the lamination direction is approximately equal to the length of a photoelectric converter 10 in the lamination direction, and the length of a metal layer 51 in the lamination direction is approximately half of the length of the photoelectric converter 10 in the lamination direction. In addition, as shown in FIG. 20, the lower end of the metal layer 51 may be configured to be aligned with (e.g., coplanar with) the lower end of the photoelectric converter 10. Alternatively, as shown in FIG. 21, the length of each of a metal layer 51 and a dielectric layer 52 in the lamination direction may be approximately half of the length of the photoelectric converter 10 in the lamination direction, and the upper end of the metal layer 51 may be configured to be aligned with (e.g., coplanar with) the upper end of the photoelectric converter 10.

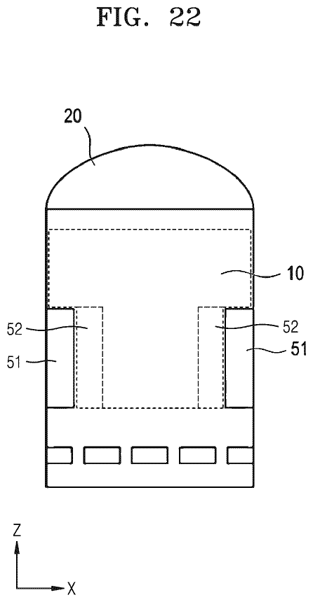

FIG. 22 is a schematic diagram of FIG. 2 and illustrates a solid-state image sensor according to Modified Example 10.

As shown in FIG. 22, the length of each of a metal layer 51 and a dielectric layer 52 in the lamination direction is approximately half of the length of a photoelectric converter 10 in the lamination direction, and the lower end of the metal layer 51 may be configured to be aligned (e.g., coplanar) with the lower end of the photoelectric converter 10.

In FIGS. 21 and 22, regions in a pixel isolator 50, in which the metal layer 51 and the dielectric layer 52 are not formed, are pixel-isolated by doping. In some example embodiments, the metal layer 51 is covered by the dielectric layer 52, and thus, the length of the dielectric layer 52 is greater than the length of the metal layer 51.

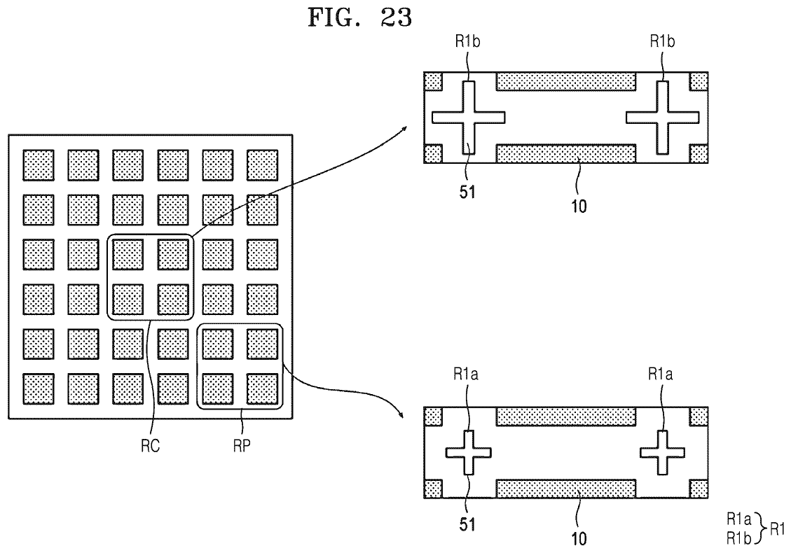

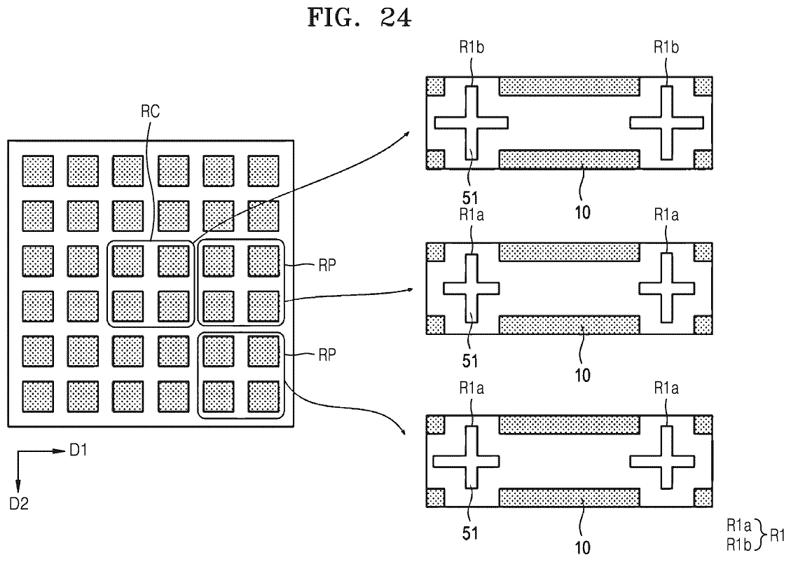

FIG. 23 is a diagram illustrating a solid-state image sensor according to Modified Example 11. FIG. 24 is a diagram illustrating a solid-state image sensor according to Modified Example 12.

In some example embodiments, including the example embodiments shown in FIGS. 1 to 22 and as described above, the first regions R1 of the metal layer 51 may have the same shape at all locations. However, as shown in FIGS. 23 and 24, the shapes of the first regions R1 of the metal layer 51 may be different from each other in a central pixel region and a peripheral pixel region.

In some example embodiments, the solid-state image sensor 1 includes one or more central pixel array regions RC at a center of the plurality of pixels 90 and one or more peripheral pixel array regions RP at least partially surrounding the central pixel array region(s) RC, and the first regions R1 of the solid-state image sensor 1 include a first portion R1a of first regions and a second portion R1b of first regions, where the first portion R1a of first regions are in one or more of the peripheral pixel array regions RP and the second portion R1b of first regions are in one or more of the central pixel array regions RC. The first portion(s) R1a of first regions in one or more peripheral pixel array regions RP may each be defined by a first volume of metal layer 51, and the second portion(s) R1a of first regions in one or more central pixel array regions RC may each be defined by a second volume of metal layer 51. The first volume of the metal layer 51 defining the first portion(s) R1a of first regions in one or more peripheral pixel array regions RP may be smaller than the second volume of the metal layer 51 defining the second portion(s) R1b of first regions in one or more central pixel array regions RC, for example such that the first portion(s) of first regions R1a in the one or more peripheral pixel array regions RP may each have a smaller volume than a second portion of the first regions R1b in the one or more central pixel array regions RC. For example, as shown in FIG. 23, the volume of the metal layer 51 is set to be smaller at the peripheral pixel region RP than at the central pixel region RC. This suppresses the degradation of QE at the peripheral pixel region.

In some example embodiments, the first portion(s) R1a of first regions in one or more peripheral pixel array regions RP may each define a radially asymmetric shape in a horizontal plane that is perpendicular to the lamination direction Z and in which the horizontal direction X, first direction D1, second direction D2, or any combination thereof (which may each extend in parallel or substantially in parallel to the backside 11a of the substrate 11) may extend, and the second portion(s) R1b of first regions in one or more central pixel array regions RC may each define a radially symmetric shape in the horizontal plane or a shape having greater radial symmetry in the horizontal plane than the first portion(s) R1a of first regions in one or more peripheral pixel array regions RP. For example, the first portion(s) R1a of first regions in one or more peripheral pixel array regions RP may each define a shape in plan view (e.g., in the horizontal plane) having a greater radial asymmetry in the horizontal plane than a shape defined by the second portion(s) R1b of first regions in one or more central pixel array regions RC. It will be understood that “radial” symmetry, asymmetry or the like may be interchangeably referred to herein as “rotational” symmetry, asymmetry, or the like. For example, as shown in FIG. 24, the metal layer 51 in one or more peripheral pixel array regions RP may be asymmetrical in the up-down and left-right directions relative to the direction in which light is incident at an oblique angle (e.g., may have radial and/or rotational asymmetry in plan view such as shown in FIG. 24). As further shown in FIG. 24, the metal layer 51 in a central pixel array region RC may be symmetrical in the up-down and left-right directions relative to the direction in which light is incident at an oblique angle (e.g., may have radial and/or rotational symmetry in plan view such as shown in FIG. 24). It will be understood that a second portion Rib of first regions in a central pixel array region RC may be radially asymmetrical, and a first portion R1b of first regions in a peripheral pixel array region RP may have greater radial asymmetry than the second portion R1b of first regions in the central pixel array region RC.

Specifically, the metal layer 51 is arranged so that the volume of the metal layer 51 is relatively large at a location facing the direction in which the light is incident. This suppresses the degradation of MTF at the peripheral pixel region.

In some example embodiments, including the example embodiments shown in FIGS. 1 to 24 and as described above, the solid-state image sensor 1 has the periodic structure 60. However, a solid-state image sensor in some example embodiments may not have a periodic structure.

In some example embodiments, including the example embodiments shown in FIGS. 1 to 24 and as described above, the first regions R1 are formed in the diagonal directions. Also, in Modified Example 1, the first regions R3 are formed between adjacent photoelectric converters 10. However, the first regions may be formed at any location other than on four places of the photoelectric converter 10.

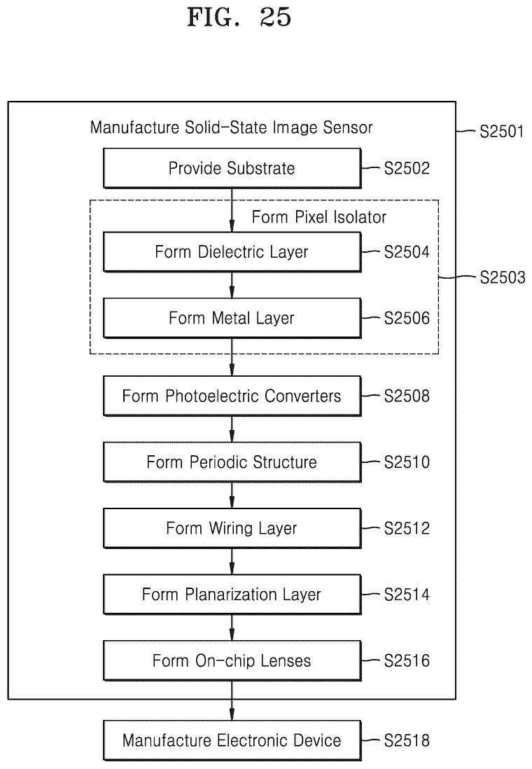

FIG. 25 illustrates a flowchart of a method according to some example embodiments. The method as shown in FIG. 25 is described with reference to the solid-state image sensor 1 shown in FIGS. 1 to 4, but it will be understood that the solid-state image sensor manufactured according to the method may be a solid-state image sensor according to any of the example embodiments. It will be understood that the order of operations in the method may be changed relative to the order shown in FIG. 25. It will be understood that one or more of the operations of the method shown in FIG. 25 may be omitted, rearranged, or the like. It will be understood that one or more operations may be added to the method shown in FIG. 25.

As shown in FIG. 25, the method may include a method of manufacturing a solid-state image sensor S2501 which may include some or all of operations S2502 to S2516.

At S2502, a substrate 11 is provided. The substrate 11 may be a substrate according to any of the example embodiments. The substrate 11 may include dopants having a first conductivity type (e.g., a p-type). For example, the substrate 11 may be a substrate in which an epitaxial layer having the first conductivity type is formed on a bulk silicon substrate having the first conductivity type. In some example embodiments, the substrate 11 may be a bulk substrate including a well having the first conductivity type. In some example embodiments, the provided substrate 11 does not include any p-type or n-type dopants.

At S2503, a pixel isolator 50 according to any of the example embodiments is formed to isolate regions 70 of the substrate 11 from each other in a horizontal plane perpendicular to the lamination direction (e.g., in a plane extending parallel to a backside 11a and/or a frontside 11b of the substrate 11) such that the regions 70 of the substrate 11 at least partially overlap each other in the horizontal direction. As shown, the forming of the pixel isolator 50 may include forming the dielectric layer 52 according to any of the example embodiments at S2504 and forming the metal layer 51 according to any of the example embodiments at S2506.

At S2504, a dielectric layer 52 is formed to at least partially define the pixel isolator 50. The dielectric layer 52 may be formed based on forming a trench TR1 into the substrate 11 from one or both of the backside 11a or the frontside 11b of the substrate 11. A mask (not shown) may be formed on the substrate 11 (e.g., at the backside 11a and/or at the frontside 11b), and the substrate 11 may be anisotropically etched using the mask (not shown) as an etch mask to form the trench TR1. The dielectric layer 52 may be formed based on depositing a material comprising the dielectric layer 52 as described herein (e.g., a dielectric material) to at least cover an inner surface of the trench TR2 and/or to fill (e.g., partially or entirely fill) the trench TR2.

At S2506, a metal layer 51 is formed to at least partially define the pixel isolator 50. The metal layer 51 may be formed based on forming a trench TR2 from one or both of the backside 11a or the frontside 11b of the substrate 11, the trench TR2 extending into the dielectric layer 52 formed at S2504. In some example embodiments, where the dielectric layer 52 is formed to fill the trench TR1, a mask (not shown) may be formed on the substrate 11 and a portion of the dielectric layer 52, and a portion of the dielectric layer 52 exposed by the mask may be anisotropically etched using the mask (not shown) as an etch mask to form the trench TR2 as a trench that is at least partially defined by inner surfaces of the dielectric layer 52, and the metal layer 51 may be formed based on depositing a metal comprising the metal layer 51 as described herein to fill (partially or entirely fill) the trench TR2.

At S2508, the plurality of photoelectric converters 10 may be formed in the substrate 11. For example, at S2508 one or more dopants may be injected into the substrate 11 in the separate, respective regions 70 defined, and isolated from each other in the horizontal plane by, the pixel isolator 50 to form photoelectric converters 10 in the substrate 11 such that the photoelectric converters 10 at least partially define separate, respective pixels 90 and the pixel isolator 50 isolates the pixels 90 from each other. The photoelectric converters 10 may have a second conductivity type (e.g., an n-type) different from the first conductivity type (e.g., the p-type) or may include regions having the first conductivity type (e.g., p-type region) and having the second conductivity type (e.g., n-type region). In some example embodiments, including example embodiments where the substrate 11 as provided at S2502 does not include any p-type or n-type dopants, the doping at S2504 may include doping a first part of each of the regions 70 defined by the pixel isolator 50 with a p-type dopant and doping another, second part of each of the regions 70 defined by the pixel isolator 50 with an n-type dopant to form a pn junction in each of the regions defined by the pixel isolator 50.

At S2510, a periodic structure 60 having periodicity (e.g., period P) in the horizontal direction X may be formed on one of both of the backside 11a and/or the frontside 11b of the substrate 11, and/or may be formed on one or both (opposite) sides of the photoelectric converters 10 at the backside 11a and/or the frontside 11b of the substrate 11. For example, S2510 may include forming one of the first or second portions 60a or 60b of the periodic structure 60 on one side of the photelectric converters (e.g., at backside 11a or frontside 11b) and further forming another one of the first or second portions 60a or 60b of the periodic structure 60 on another, opposite side of the photelectric converters (e.g., at backside 11a or frontside 11b). The first and second portions 60a and 60b may each independently be formed based on forming a continuous layer on the substrate 11 which comprises a material of one of the first layer 61 or the second layer 62, etching trenches having period P into the formed continuous layer, and filling the trenches with the material of the other one of the first layer 61 or the second layer 62. In some example embodiments, the forming of the periodic structure 60 on one or both of the backside 11a and/or the frontside 11b of the substrate 11 may include forming the first and/or second portions 60a and/or 60b to include the alternating first and second layers 61 and 62 as one or more separate structures defining at least one of the first portion 60a or the second portion 60b and laminating said separate structure(s) on the substrate 11.

In some example embodiments, forming the periodic structure 60 at S2510 may include thinning the substrate 11 at the backside 11a and/or the frontside 11b so as to expose at least a portion of the pixel isolator 50 in the horizontal direction X, including exposing at least a portion of the metal layer 51 and/or the dielectric layer 52 from the substrate 11, and forming the first and/or second portions 60a and/or 60b of the periodic structure 60 to cover the exposed portions of the pixel isolator 50 in the horizontal direction X.

At S2512, a wiring layer 30 may be formed on the front surface (frontside 11b) of the substrate 11. The wiring layer 30 may be formed based on forming multiple separate wiring layers based on depositing and/or laminating one or more layers of materials in one or more sequential operations. In some example embodiments, at least a portion of the wiring layer 30 may be applied to the frontside 11b of the substrate 11 or the second portion 60b of the periodic structure 60 via lamination.

At S2514, a planarization layer 40 may be formed on the backside 11a of the substrate 11 and/or on the first portion 60a of the periodic structure 60. The planarization layer 40 may be formed based on depositing a material comprising the planarization layer 40 as described herein to cover the back surface (backside 11a) and/or the first portion 60a of the periodic structure 60. In some example embodiments, one or more additional and/or alternative layers may be formed on the backside 11a, including for example a light-blocking layer, color filter layer, or the like, in addition to or alternative to the planarization layer 40.

At S2516, on-chip lenses 20 may be formed on the photoelectric converters 10. In some example embodiments, the on-chip lenses 20 are manufactured separately and applied (e.g., laminated) to an exposed surface (e.g., an exposed surface of the planarization layer 40, periodic structure 60, substrate 11 and/or photoelectric converters 10) to form the on-chip lenses 20.

As shown, S2502 to S2516 may at least partially comprise an operation S2501 of manufacturing a solid-state image sensor 1. It will be understood that the order of operations S2502 may be rearranged to be different from what is shown in FIG. 25.

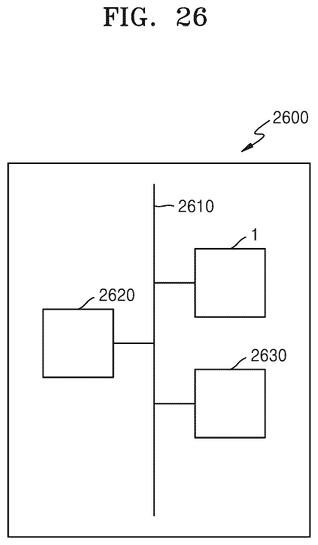

At S2518, an electronic device may be manufactured to include the solid-state image sensor 1 formed at S2501, for example based on incorporating (e.g., integrating) the solid-state image sensor 1 to an assembly that includes additional components including, for example, a processor (e.g., CPU), a memory (e.g., SSD), a communication bus connecting the components and image sensor, any combination thereof, or the like. Such an electronic device manufactured at S2518 may include the electronic device 2600 shown in FIG. 26.

FIG. 26 is a schematic view illustrating an electronic device according to some example embodiments.

Referring to FIG. 26, the electronic device 2600, which may be manufactured at S2518 of the method shown in FIG. 25, may include a bus 2610, a processor 2620, a memory 2630, and the solid-state image sensor 1 according to any of the example embodiments, where the solid-state image sensor 1 may be integrated into the electronic device 2600 at S2518 in FIG. 25. Information of the aforementioned image sensor 1, processor 2620, and memory 2630 may be transmitted to each other through the bus 2610.

The processor 2620 may include one or more articles of processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. As an example, the processing circuitry may include a non-transitory computer readable storage device. The processor 2620 may, for example, control a display operation of the solid-state image sensor 1.

The memory 2630 may store an instruction program, and the processor 2620 may perform a function (e.g., a function related to a display panel and/or the solid-state image sensor 1) by executing the stored instruction program.

The units and/or modules described herein may be implemented using hardware constituent elements and software constituent elements. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

The method according to the foregoing example embodiments may be recorded in a non-transitory computer readable storage device including program instructions for implementing various operations of the aforementioned embodiments. The storage device may also include program instructions, data files, data structures, and the like alone or in combination. The program instructions recorded in the storage device may be specially designed for the present example embodiments or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of any of the aforementioned example embodiments.

While the inventive concepts have been particularly shown and described with reference to some example embodiments thereof, it will be understood that various changes in form and details may be made therein without departing from the spirit and scope of the following claims.

What is claimed is:

1. A solid-state image sensor, comprising:
a plurality of photoelectric converters arranged in a horizontal direction such that the plurality of photoelectric converters at least partially overlap each other in the horizontal direction, the plurality of photoelectric converters at least partially defining separate, respective pixels of a plurality of pixels in the solid-state image sensor;
a plurality of on-chip lenses on one side of separate, respective photoelectric converters of the plurality of photoelectric converters in a lamination direction, the lamination direction perpendicular to the horizontal direction;
a wiring layer on another side of each photoelectric converter of the plurality of photoelectric converters in the lamination direction; and
a pixel isolator configured to isolate the plurality of pixels from each other,
wherein the pixel isolator includes a metal layer and a dielectric layer, and
in the horizontal direction, the pixel isolator includes separate first regions defined by the metal layer is located and second regions defined by at least the dielectric layer.

2. The solid-state image sensor of claim 1, wherein, in the horizontal direction, the separate first regions are diagonally arranged between adjacent pixels of the plurality of pixels.

3. The solid-state image sensor of claim 2, wherein the metal layer has a cross, rhombic, quadrangular, circular, or linear shape in the separate first regions.

4. The solid-state image sensor of claim 2, wherein a length of the metal layer in the lamination direction is greater than a wavelength of light that the plurality of photoelectric converters are configured to photoelectrically convert and is less than or equal to a thickness of the plurality of photoelectric converters in the lamination direction.

5. The solid-state image sensor of claim 2, wherein a length of the dielectric layer in the lamination direction is greater than a length of the metal layer in the lamination direction.

6. The solid-state image sensor of claim 2, wherein a boundary between the plurality of photoelectric converters and the pixel isolator is at least partially covered by the dielectric layer.

7. The solid-state image sensor of claim 2, wherein a light absorbance of the dielectric layer is smaller than a light absorbance of the metal layer.

8. The solid-state image sensor of claim 2, wherein a volume of the metal layer at least partially defines a quantum efficiency of the solid-state image sensor.

9. The solid-state image sensor of claim 2, further comprising a periodic structure located between the plurality of photoelectric converters and the plurality of on-chip lenses and having periodicity in the horizontal direction.

10. The solid-state image sensor of claim 9, wherein a period of the periodic structure corresponds to an angle of incidence of light that the plurality of photoelectric converters are configured to photoelectrically convert, and the period of the periodic structure is smaller than a wavelength of the light that the plurality of photoelectric converters are configured to photoelectrically convert.

11. The solid-state image sensor of claim 10, wherein the periodic structure is configured to diffract light incident on the periodic structure to generate diffracted light in the periodic structure.

12. The solid-state image sensor of claim 9, wherein a period of the periodic structure has a length configured to totally reflect diffracted light generated by the plurality of photoelectric converters at a boundary between at least one photoelectric converter of the plurality of photoelectric converters and the pixel isolator.

13. A solid-state image sensor, comprising:
a plurality of photoelectric converters arranged in a horizontal direction such that the plurality of photoelectric converters at least partially overlap each other in the horizontal direction, the plurality of photoelectric converters at least partially defining separate, respective pixels of a plurality of pixels in the solid-state image sensor;
a plurality of on-chip lenses, each separate on-chip lens of the plurality of on-chip lenses on an upper surface of a separate photoelectric converter of the plurality of photoelectric converters in a lamination direction, the lamination direction perpendicular to the horizontal direction;
a wiring layer on a lower surface of each photoelectric converter of the plurality of photoelectric converters in the lamination direction; and
a pixel isolator configured to isolate the plurality of pixels from each other,
wherein the pixel isolator includes
a metal layer including a metal,
a dielectric layer including a dielectric material, and
a cavity layer not including any of the metal or the dielectric material,
wherein, in the horizontal direction, the pixel isolator includes separate first regions in which the metal layer is located and second regions in which the dielectric layer is located, and
wherein, in the horizontal direction, the separate first regions are diagonally arranged between adjacent pixels of the plurality of pixels.

14. The solid-state image sensor of claim 13, wherein
the solid-state image sensor includes one or more central pixel array regions at a center of the plurality of pixels and peripheral pixel array regions at least partially surrounding the one or more central pixel array regions,
the separate first regions include a first portion of the separate first regions in the peripheral pixel array regions and a second portion of the separate first regions in the one or more central pixel array regions,
the first portion of the separate first regions are each defined by a first volume of the metal layer, and the second portion of the separate first regions are each defined by a second volume of the metal layer, the first volume different from the second volume, and
each first region in the first portion of the separate first regions defines a first shape in a horizontal plane having that is different in the horizontal plane than a second shape defined in the horizontal plane by each first region in the second portion of the separate first regions, the horizontal plane perpendicular to the lamination direction.

15. The solid-state image sensor of claim 14, wherein
the first volume is smaller than the second volume.

16. The solid-state image sensor of claim 14, wherein
the each first region in the first portion of the separate first regions defines the first shape in the horizontal plane having a greater radial asymmetry in the horizontal plane than the second shape defined in the horizontal plane by the each first region in the second portion of the separate first regions.

17. The solid-state image sensor of claim 13, wherein,
in the horizontal direction, the separate first regions are diagonally arranged between the adjacent pixels of the plurality of pixels, and
the metal layer has a cross, rhombic, quadrangular, circular, or linear shape in the separate first regions.

18. The solid-state image sensor of claim 13, wherein
a length of the metal layer in the lamination direction is greater than a wavelength of light that the plurality of photoelectric converters are configured to photoelectrically convert and is less than or equal to a thickness of the plurality of photoelectric converters in the lamination direction, and
a length of the dielectric layer in the lamination direction is greater than the length of the metal layer in the lamination direction.

19. A solid-state image sensor, comprising:
a plurality of photoelectric converters arranged in a horizontal direction such that the plurality of photoelectric converters at least partially overlap each other in the horizontal direction, the plurality of photoelectric converters at least partially defining separate, respective pixels of a plurality of pixels in the solid-state image sensor;
a plurality of on-chip lenses, each separate on-chip lens of the plurality of on-chip lenses on an upper surface of a separate photoelectric converter of the plurality of photoelectric converters in a lamination direction, the lamination direction perpendicular to the horizontal direction;
a wiring layer on a lower surface of each photoelectric converter of the plurality of photoelectric converters in the lamination direction; and
a pixel isolator configured to isolate the plurality of pixels from each other,
wherein the pixel isolator includes
a metal layer including a metal,
a dielectric layer including a dielectric material, and
a cavity layer not including any of the metal or the dielectric material, and wherein,
in the horizontal direction, the pixel isolator includes first regions in which the metal layer is located and second regions in which the dielectric layer is located,
in the horizontal direction, the first regions are diagonally arranged between adjacent pixels of the plurality of pixels,
the metal layer has a cross, rhombic, quadrangular, circular, or linear shape in the first regions,
a length of the metal layer in the lamination direction is greater than a wavelength of light that the plurality of photoelectric converters are configured to photoelectrically convert and is less than or equal to a thickness of the plurality of photoelectric converters in the lamination direction,
a boundary between the plurality of photoelectric converters and the pixel isolator is at least partially covered by the dielectric layer,
a length of the dielectric layer in the lamination direction is greater than the length of the metal layer in the lamination direction, and
a light absorbance of the dielectric layer is smaller than a light absorbance of the metal layer.

20. The solid-state image sensor of claim 19, wherein
the solid-state image sensor includes one or more central pixel array regions at a center of the plurality of pixels and peripheral pixel array regions at least partially surrounding the one or more central pixel array regions,
the first regions include a first portion of the first regions in the peripheral pixel array regions and a second portion of the first regions in the one or more central pixel array regions,
the first portion of the first regions are each defined by a first volume of the metal layer, the second portion of the first regions are each defined by a second volume of the metal layer, and the first volume is smaller than the second volume, and
each first region in the first portion of the first regions defines a first shape in a horizontal plane having a greater radial asymmetry in the horizontal plane than a second shape defined in the horizontal plane by each first region in the second portion of the first regions, the horizontal plane perpendicular to the lamination direction.
